(19) United States
(12) Patent Application Publication
(10) Pub. No.: US 2026/0096430 A1
(43) Pub. Date: Apr. 2, 2026

(54) POWER SUPPLY MODULE FOR IMMERSION COOLING, SIGNAL CONNECTION SUBSTRATE, AND AN ASSEMBLY AND MANUFACTURING METHOD

(71) Applicant: MetaPWR Electronics Co., Ltd., Shanghai (CN)

(72) Inventors: Shouyu HONG, Shanghai (CN); Jianhong ZENG, Shanghai (CN); Hongxiu LIU, Shanghai (CN); Yahong Xiong, Shanghai (CN)

(73) Assignee: MetaPWR Electronics Co., Ltd., Shanghai (CN)

(21) Appl. No.: 19/340,892

(22) Filed: Sep. 26, 2025

(30) Foreign Application Priority Data
Sep. 28, 2024 (CN) 202411364219.X

(51) Int. Cl. H01L 23/473; H01L 21/48; H01L 23/552; H01L 25/07; H10D 80/20

(52) U.S. Cl. CPC H10W 40/47; H10D 80/215; H10D 80/251; H10W 40/037; H10W 42/20; H10W 90/00

(57) ABSTRACT

The present invention is directed to a power supply module for immersion cooling, by providing uneven edges between the edge of the metal layer of the upper surface and the lower surface of the third substrate and the edge of the third substrate, the design of the spacing between adjacent metal layers and the design of the height of the gap between the third substrate and the first substrate or the second substrate, the faults and failures caused by the conductive particles in the cooling fluid are reduced. On the other hand, by dispensing glue at the key position between the first substrate and the third substrate and between the second substrate and the third substrate, the possibility that the conductive particles fluid into the power supply module is further reduced. The present invention further discloses several structures and manufacturing processes of the third substrate for immersion cooling.

### CROSS-REFERENCE TO RELATED APPLICATIONS

This application claims the priority benefit of Chinese patent application CN202411364219.X filed on Sep. 28, 2024. The entirety of the above-mentioned patent application is hereby incorporated by reference herein and made a part of this specification.

### BACKGROUND

### Technical Field

The present disclosure relates to the technical field of power supply module, and in particular to power supply module for immersion cooling, signal connection substrate, and an assembly and manufacturing method.

### Description of Related Art

With the increasing requirements of various types of artificial intelligence, data processing, etc. the computing power of various types of cards is continuously increased, and the power consumption of a computing chip is also increased year by year. At the same time, since the size limitation of these computing power units is extremely high, higher and higher requirements are provided for the occupied area, heat dissipation, etc. of the energy processing unit.

In order to reduce the footprint of the energy processing unit, the 3D stacked power supply module becomes a trend; in order to improve the heat dissipation performance of the power supply module, immersion cooling can be used. However, some conductive particles, such as solder balls from the surface of the PCBA assembly, are easily entrained in the cooling liquid. These conductive particles may flow in the cooling liquid, which may create short-circuited between adjacent electrodes, resulting in some functional failures and even catastrophic failures such as burning loss or failure of the power supply module and the computing chip.

Generally, the pitch of the power pins of the power supply module is relatively large, and the conductive particles can be ablated by transient discharge. However, the pitch of the signal pin is relatively small, and it is easy to be short-circuited by the conductive particle, causing an abnormality in a driving signal or a control signal or a sampling signal; for example, the abnormality of the driving signal may cause the switch bridge arm to short-through, thereby causing the power device to burn out; and the abnormality of the control signal may cause the power supply module to be powered off, etc. Therefore, how to protect the signal pins from being bridged by the conductive particle is an urgent problem to be solved currently.

### SUMMARY

In view of the above, one of the objectives of the invention is to provide a power supply module for immersion cooling, comprising a first substrate, a third substrate, a passive element, a semiconductor device and a capacitor, wherein the first substrate comprises an upper surface and a lower surface opposite to each other, the semiconductor device is arranged on the upper surface of the first substrate, the capacitor is welded on the first substrate, and the lower surface of the first substrate is provided with a pad;
the third substrate comprises an upper surface and a lower surface opposite to each other, and a first side surface and a second side surface opposite to each other, the passive element comprises an upper surface and a lower surface opposite to each other, the upper surface of the third substrate and the upper surface of the passive element are attached to a lower surface of the first substrate, and a second side surface of the third substrate is disposed adjacent to one side surface of the passive element;
an upper surface and a lower surface of the third substrate are respectively provided with a metal layer, the first side surface is provided with an insulating layer, and the shortest distance between the first side surface and the edge of an adjacent metal layer is greater than zero;
a metal layer of the upper surface of the third substrate is fixed and electrically connected to a portion of the pads of the lower surface of the first substrate by means of a conductive material, a portion of the pads of the lower surface of the first substrate is disposed in a vertical projection of the third substrate on the lower surface of the first substrate, and the shortest distance between the vertical projection line of the first side surface of the third substrate on the lower surface of the first substrate and the adjacent portion of the pads on the lower surface of the first substrate is greater than zero;
the upper surface and the lower surface of the passive element are respectively provided with a metal layer, and the metal layer on the upper surface of the passive element is fixed and electrically connected to a portion of the pads on the lower surface of the first substrate by means of a conductive material.

Preferably, further comprising a second carrier, wherein the second carrier comprises an upper surface and a lower surface, the upper surface and the lower surface are both provided with pads, the pads of the upper surface are fixed and electrically connected to the metal layer on the lower surface of the third carrier and the metal layer on the lower surface of the passive element by means of a conductive material, and the pads on the lower surface of the second carrier are used for being fixed and electrically connected to the external assembly.

Preferably, wherein a spacing between adjacent metal layers of the upper surface of the third substrate is greater than a gap height between the first substrate and the third substrate.

Preferably, wherein a spacing between adjacent metal layers of the upper surface of the third substrate is greater than twice a gap height between the first substrate and the third substrate, and the gap height is less than 0.2 mm.

Preferably, wherein a spacing between adjacent metal layers of the lower surface of the third substrate is greater than a gap height between the second substrate and the third substrate.

Preferably, wherein a spacing between adjacent metal layers of the lower surface of the third substrate is greater than twice a gap height between the second substrate and the third substrate, and the gap height is less than 0.2 mm.

Preferably, wherein a width of the metal layer of the third substrate is greater than or equal to a shortest distance from an edge of the metal layer of the third substrate to the first side surface and/or the second side surface of the third substrate.

Preferably, wherein a width of the metal layer of the third substrate is greater than or equal to 0.2 mm, and a shortest distance from an edge of the metal layer of the third substrate to the first side surface and/or the second side surface of the third substrate is equal to 0.2 mm.

Preferably, wherein the third substrate and the passive element are fixed by a bonding material, and an average thickness of the bonding material is less than a spacing between adjacent metal layers of the upper surface of the third substrate.

Preferably, wherein an average thickness of the bonding material is less than ½ of a spacing between adjacent metal layers of the upper surface of the third substrate.

Preferably, wherein a vertical projection of the third substrate on the lower surface of the first substrate is within the lower surface of the first carrier, and a shortest distance between an edge of the vertical projection and an edge of the lower surface of the adjacent first substrate is greater than zero.

Preferably, wherein an edge of the passive element adjacent to the third substrate and the first substrate comprises a chamfer, a channel exists among the passive element and the first substrate and the third substrate, dispense glue at both ends of the channel.

Preferably, wherein an edge of the passive element adjacent to the third substrate and the second substrate comprises a chamfer, a channel exists among the passive element and the second substrate and the third substrate, and dispense glue at both ends of the channel.

Preferably, wherein a gap between the first substrate and the third substrate is blocked with glue, or apply an underfill material to the gap.

Preferably, wherein a gap between the second substrate and the third substrate is blocked with glue, or apply an underfill material to the gap.

Preferably, wherein the third substrate comprises a metal frame, and the metal frame is electrically connected to the metal layer on the upper surface and on the lower surface of the third substrate.

Preferably, wherein the pin positions of the metal layer of the upper surface of the third substrate and the pin positions of the metal layer of the lower surface of the third substrate are in one-to-one correspondence, and the metal frame directly extends from the metal layer of the upper surface to the metal layer of the lower surface.

Preferably, wherein at least part of the pin positions of the metal layer of the upper surface of the third substrate and the pin positions of the metal layer of the lower surface of the third substrate are staggered, and the metal frame from the metal layer of the upper surface of the third substrate to the vertically corresponding metal layer of the lower surface of the third substrate is split in the middle.

Preferably, wherein the third substrate further comprises a shielding layer, and the shielding layer is disposed on a side surface of the third substrate and/or inside the third substrate. Preferably, wherein the shielding layer is disposed between the metal frame and the passive element.

Preferably, wherein the third substrate is a multi-layer circuit plate, and the shielding layer is electrically connected to the metal frame through a via hole.

Preferably, wherein the shielding layer is configured in different zones, and the shielding layer of each zone is connected to different potentials on the metal frame.

Preferably, wherein the metal layer on the upper surface of the third substrate is recessed in the upper surface, and the metal layer on the lower surface of the third substrate is recessed in the lower surface.

Preferably, wherein a height of the third substrate is greater than a height of the passive element.

A method for manufacturing the third substrate, wherein the third substrate is formed by injection molding, first manufacturing a metal frame, then covering one surface or two opposite surfaces of the metal frame using an injection molding process.

The manufacturing method of the third substrate, wherein the third substrate is manufactured by using a printed circuit plate embedded copper process, and comprises the following steps:
Step 1: first manufacturing a semi-etched copper frame;
Step 2: laminating a prepreg on one side of the semi-etching to form an insulating layer;

Step 3: continually etching on the side of the copper frame unetched.

Preferably, wherein the step of manufacturing the third substrate further comprises:
Step 4a: on the side of continuing etching in Step 3, continuing to laminate the prepreg to form an insulating layer.

Preferably, wherein the step of manufacturing the third substrate further comprises:
Step 4b: stacking another insulating core plate on the outer side of the insulating layer of Step 2 by means of a low-temperature curing medium.

A signal connection substrate, comprising an upper surface and a lower surface opposite to each other, and a first side surface and a second side surface opposite to each other, wherein the signal connection substrate is a multi-layer circuit plate, and at least three metal layers are provided on the upper surface and the lower surface of the signal connection substrate respectively;
the pin positions of the metal layer of the upper surface and the pin positions of the metal layer of the lower surface are arranged in a staggered manner;
the signal connection substrate further comprises a shielding layer arranged on the first side surface of the signal connection substrate and/or on the second side surface of the signal connection substrate and/or in the signal connection substrate;
an insulating layer is provided between the metal layer and the first side surface;
the signal connection substrate is used for a stacked power supply module.

Preferably, wherein the signal connection substrate further comprises a metal frame, and the metal frame is electrically connected to the metal layer of the upper surface and the metal layer of the lower surface.

Preferably, wherein the multilayer circuit plate is a multilayer printed circuit plate or a composite multi-layer circuit plate.

Preferably, wherein at least part of the metal frame between the metal layer of the upper surface and the vertically corresponding metal layer of the lower surface is split in the middle, and the metal layer of the upper surface and the metal layer of the lower surface with the same pin position are electrically connected through the metal frame, the via hole and the inner wiring layer.

Preferably, wherein the shielding layer is electrically connected to the metal frame through a via hole.

Preferably, wherein the shielding layer is arranged in different zones, and a shielding layer of each zone is connected to different potentials on the metal frame.

Preferably, wherein the metal layer on the upper surface of the third substrate is recessed in the upper surface, and the metal layer on the lower surface of the third substrate is recessed in the lower surface.

Preferably, wherein a shortest distance from an edge of the metal layer to the first side surface and/or the second side surface of the signal connection substrate is greater than or equal to 0.2 mm.

A method for manufacturing a signal connection substrate, wherein the signal connection substrate is manufactured by using a printed circuit plate embedded copper process, and comprises the following steps:
Step 1: first manufacturing a semi-etched copper frame;
Step 2: laminating a prepreg on one side of the semi-etching to form an insulating layer;
Step 3: continually etching on the side of the copper frame unetched.

Preferably, wherein the step of manufacturing the signal connection substrate further comprises Step 4a: on the side of continuing etching in Step 3, continuing to laminate the prepreg to form an insulating layer.

Preferably, wherein the manufacturing step of the signal connection substrate further comprises Step 4b: stacking another insulating core plate on the outer side of the insulating layer of Step 2 by means of a low-temperature curing medium.

A method for manufacturing a signal connection substrate, wherein the signal connection substrate is formed by injection molding, first manufacturing a metal frame, then covering one surface or two opposite surfaces of the metal frame using an injection molding process.

An assembly, wherein the assembly is used for a stacked power supply module, comprising an upper surface and a lower surface opposite to each other, a signal connection substrate and a passive element; the signal connection substrate comprises an upper surface and a lower surface opposite to each other, and a first side surface and a second side surface opposite to each other; the passive element comprises an upper surface and a lower surface opposite to each other; the second side surface of the signal connection substrate is arranged adjacent to one side surface of the passive element; the upper surface and the lower surface of the signal connection substrate are respectively provided with a metal layer, and the metal layer on the upper surface of the signal connection substrate is electrically connected to the corresponding metal layer of the lower surface;
an insulating layer is disposed between the metal layer and the first side surface of the signal connection substrate;
the upper surface and the lower surface of the passive element are respectively provided with a metal layer, and the upper surface and the lower surface of the passive element each comprises at least one metal layer for transmitting power;
the metal layer of the upper surface of the signal connection substrate is coplanar with the metal layer of the upper surface of the passive element, and the metal layer of the lower surface of the signal connection substrate is coplanar with the metal layer of the lower surface of the passive element;
a shortest distance between the first side surface and an edge of an adjacent metal layer is greater than zero.

Preferably, wherein the passive element is a magnetic element comprising at least two alternating current windings.

Preferably, wherein the passive element further comprises at least one direct current pin, and the direct current pin covers a part of the upper surface, a part of a side surface and a part of the lower surface of the passive element, and is used for transferring energy between the upper surface and the lower surface of the passive element.

Preferably, wherein the second side surface of the signal connection substrate is provided with an insulating layer.

Preferably, wherein the thickness of the insulating layer is at least 0.2 mm.

Preferably, wherein the passive element and the signal connection substrate are fixed by a bonding material.

A method for manufacturing the assembly, comprising the following steps:
Step 1: setting the thickness of the exposed metal layer on the upper surface and the lower surface of the signal connection substrate to be at least 0.2 mm, and bonding the signal connection substrate and the passive element together by means of a bonding material to form an assembly;
Step 2: grinding the upper surface and the lower surface of the assembly;

Step 3: solder resist processing is performed on the upper surface and the lower surface of the grinded assembly.

Compared with the prior art, the application has the following beneficial effects:

(1) The present invention provides a power supply module for immersion cooling. By providing an uneven edges between the edge of the metal layer of the upper surface and the lower surface of the third substrate and the edge of the third substrate, the design of the spacing between adjacent metal layers and the design of the height of the gap between the third substrate and the first substrate or the second substrate, the faults and failures caused by the conductive particles in the cooling fluid are reduced.

(2) On the other hand, by dispensing glue at the key position between the first substrate and the third substrate and between the second substrate and the third substrate, the possibility that the conductive particles fluid into the power supply module is further reduced.

(3) The present invention further discloses several structures and manufacturing processes of the third substrate for immersion cooling.

### BRIEF DESCRIPTION OF THE DRAWINGS

FIGS. 1A and 1B are perspective views of a power supply module for immersion cooling.

FIG. 2A and FIG. 2B are schematic top views of a power supply module.

FIG. 3 is a side view of a power supply module.

FIG. 4A to FIG. 4C are another side view of the power supply module.

FIG. 5 is a schematic diagram of a combination of a third substrate and a passive element.

FIG. 6A to FIG. 6C are different structures of a third substrate.

FIG. 7A to FIG. 7B are another schematic structural diagram of a metal frame.

### DESCRIPTION OF THE EMBODIMENTS

One of the cores of the present invention is to provide a power supply module for immersion cooling,

Technical solutions in the embodiments of the present disclosure will be clearly and completely described below with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

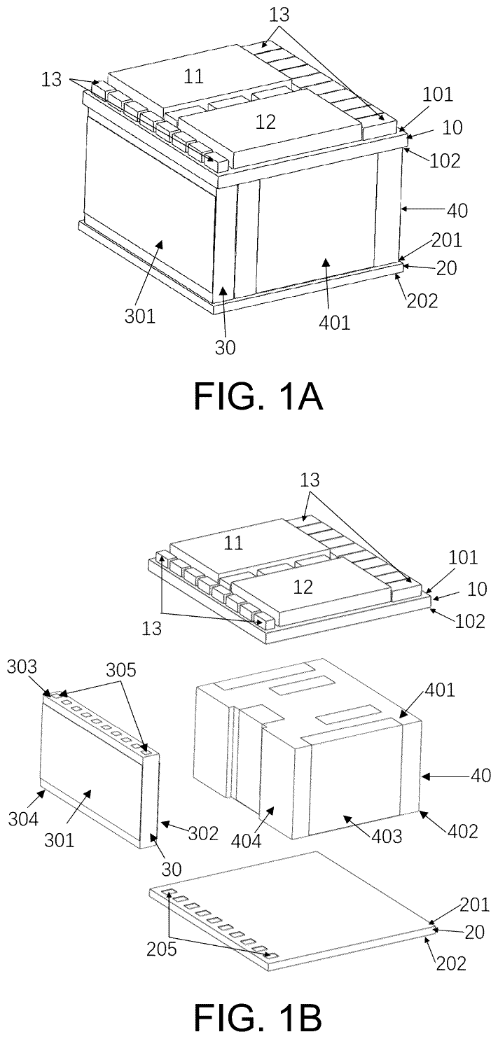

The power supply module for immersion cooling provided by the present invention is shown in FIG. 1A and FIG. 1B, wherein FIG. 1A is a three-dimensional schematic diagram of a power supply module, and FIG. 1B is an exploded schematic diagram of a power supply module. Referring to FIGS. 1A and 1B simultaneously, the power supply module for immersion cooling comprises a first substrate 10, a second substrate 20, a third substrate 30 and a passive element 40. The first substrate 10 comprises an upper surface 101 and a lower surface 102 opposite to each other, semiconductor devices 11 and 12 and the capacitor are arranged on the upper surface 101; a plurality of pads are arranged on the lower surface 102 (not shown); in other embodiments, the capacitor may also be disposed on the lower surface 102. The second substrate 20 comprises an upper surface 201 and a lower surface 202 opposite to each other, a plurality of pads 205 are disposed on the upper surface 201; a plurality of pads (not shown) are provided on the lower surface 202 for being fixed and electrically connected to the external assembly; the power supply module enables transfer energy and other signals with external components by means of the plurality of pads. The third substrate 30 comprises a first side surface 301 and a second side surface 302 opposite to each other and an upper surface 303 and a lower surface 304 which are opposite to each other, and a plurality of metal layers are respectively arranged on the upper surface 303 and the lower surface 304. In the present embodiment, the metal layer on the upper surface 303 is a single-row array, and the metal layer on the lower surface 304 is also a single-row array. In other embodiments, the metal layer on the upper surface 303 or the lower surface 304 may also be a multi-row array, or a plurality of rows of staggered arrays, thereby meeting different lcad/pin density requirements. The third substrate 30 is arranged between the first substrate 10 and the second substrate 20, the metal layer of the upper surface 303 is fixed and electrically connected to a corresponding pad of the lower surface 102 of the first substrate 10, and the metal layer of the lower surface 304 is fixed and electrically connected to a corresponding pad of the upper surface 201 of the second substrate 20. The passive element 40 comprises an upper surface 401 and a lower surface 402 opposite to each other, the passive element 40 is also arranged between the first substrate 10 and the second substrate 20, a metal layer of the upper surface 401 is fixed and electrically connected to a corresponding pad of the lower surface 102 of the first substrate 10, and a metal layer (not shown) of the lower surface 402 is fixed and electrically connected to a corresponding pad of the upper surface 201 of the second substrate 20. A second side surface 302 of the third substrate is disposed adjacent to one side surface 404 of the passive element.

In other embodiments, the power supply module for immersion cooling may not include a second substrate 20, and the metal layer disposed on the lower surface 304 and the lower surface 402 is fixed and electrically connected to the external assembly.

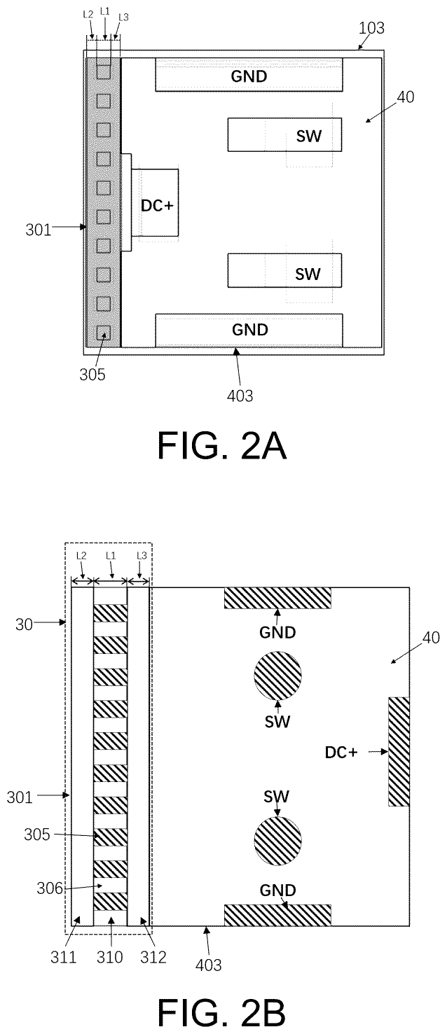

Detailed, as shown in FIG. 2A and FIG. 2B, FIG. 2A is a top partial perspective view, and FIG. 2B is a schematic top layout diagram after removing the first substrate 10. As shown in FIG. 2A, the gray area is on the upper surface 303 of the third substrate 30, the area in the outermost frame 103 is the coverage area of the first substrate 10 in the vertical direction, the vertical projection of the upper surface 303 on the lower surface 102 is all on the lower surface 102, and the shortest distance between the edge of the projection and the edge of the adjacent lower surface 102 is greater than zero (i.e. not aligned). The shortest distance between the vertical projection line of the first side surface 301 of the third substrate on the lower surface 102 of the first substrate and the partial pad of the adjacent lower surface 102 of the first substrate is greater than zero. Optionally, a part of the pads of the lower surface 102 of the first substrate is arranged in the vertical projection of the third substrate 30 on the lower surface 102 of the first substrate. The width of the metal layer 305 on the upper surface of the third substrate 30 in the horizontal direction is L1, the shortest distance from the edge of the metal layer 305 to the first side surface 301 is L2, the shortest distance from the edge of the metal layer 305 to the second side surface 302 is L3. The design is that L1≥L2, L1≥L3; and the width L1 of the metal layer 305 may be designed to L1≥0.3 mm, and the shortest distance L2=L3≥0.2 mm; optimally, the width L1 of the metal layer 305 is L1≥0.2 mm, and the shortest distance L2=L3=0.2 mm. The upper surface 401 of the passive element 40 comprises a metal layer GND, a metal layer SW and a metal layer DC+, wherein the metal layer SW is electrically connected to the semiconductor device 11/12 by means of the first substrate 10, and the metal layer GND is electrically connected to the semiconductor device 11/12 and the capacitor 13 by means of the first substrate 10; the metal layer DC+covers a part of upper surface, a part of side surface and a part of lower surface, and is electrically connected to the semiconductor device 11/12 and the capacitor 13 by means of the first substrate 10, and is electrically connected to the external assembly by means of the second substrate 20. In addition, the metal layer 305 of the upper surface 303 and the metal layer 305 of the lower surface 304 are connected by a metal frame (not shown) provided in the third substrate, the metal frame being electrically connected to the metal layer 305 provided on the upper surface and the metal layer 305 provided on the lower surface of the third substrate, and the electrical connection between the first substrate 10 and the second substrate 20 is realized by means of the metal frame, i.e. achieving signal transmission between the external assembly and the semiconductor device 11/12. In this embodiment, the pin positons of the upper surface metal layer are in one-to-one correspondence with the pin positions of the lower surface metal layer, and the metal frame directly extends from the upper surface metal layer to the corresponding lower surface metal layer.

The top layout schematic is shown in FIG. 2B, the third substrate 30 comprises an middle layer 310, a first insulating layer 311 and a second insulating layer 312. The first insulating layer 311 and the second insulating layer 312 are respectively provided on two opposite sides of the middle layer 310, the upper surface of the middle layer 310 is provided with a metal layer 305, and the insulating fixing material 306 is provided between adjacent metal layers 305. The design here is that the width L1 of the middle layer is larger than or equal to the width L2 of the first insulating layer 311, and the width L1 of the middle layer is larger than or equal to the width L3 of the second insulating layer 312. The width L1 of the metal layer 305 may be greater than or equal to 0.3 mm, and the shortest distance L2=L3≥0.2 mm. Optimally, the width L1 of the middle layer is greater than or equal to 0.2 mm and the width L2 of the first insulating layer and the width L3 of the second insulating layer are 0.2 mm. The upper surface 401 of the passive element 40 comprises a metal layer GND, a metal layer SW and a metal layer DC+, and the layout of the metal layers can be set according to actual requirements; functions of the metal layers are the same as those in FIG. 2A, and details are not described herein again.

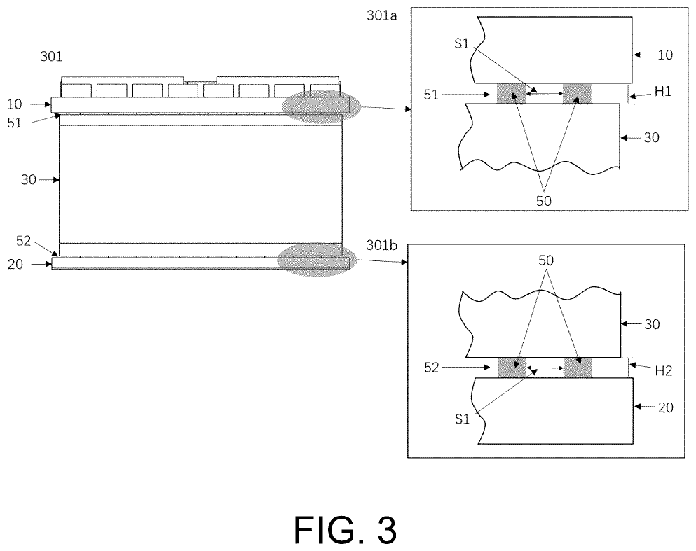

FIG. 3 shows a side view of the power supply module at the angle of the first side surface 301, 301a is an enlarged view of the connection between the first substrate 10 and the third substrate 30, 301b is an enlarged view of the connection between the second substrate 20 and the third substrate 30.

With reference to 301a, the first substrate 10 and the third substrate 30 are fixed and electrically connected by means of a conductive material 50, and the conductive material 50 is provided between the metal layer 305 of the upper surface 303 and a corresponding pad (not shown) on the lower surface 102; the height of the gap 51 between the first substrate 10 and the third substrate 30 is H1, and the gap height H1 should be less than 0.2 mm, so as to be optimal less than 0.1 mm; here, the spacing S1 between adjacent conductive materials is greater than the gap height H1, and preferably, S1≥2*H1 is optimal, and S1>3*H1 can even be reached; so that failure of adjacent electrode shorts caused by conductive particles in immersion cooling is reduced.

Similarly, as shown in 301b, the height of the gap 52 between the second substrate 20 and the third substrate 30 is H2, the gap height H2 should be less than 0.2 mm, optimally, the gap height H2 is less than 0.1 mm; the spacing S1 between adjacent conductive materials is greater than the gap height H2, and preferably, S1>2*H2 is optimal, and S1>3*H2 may even be achieved.

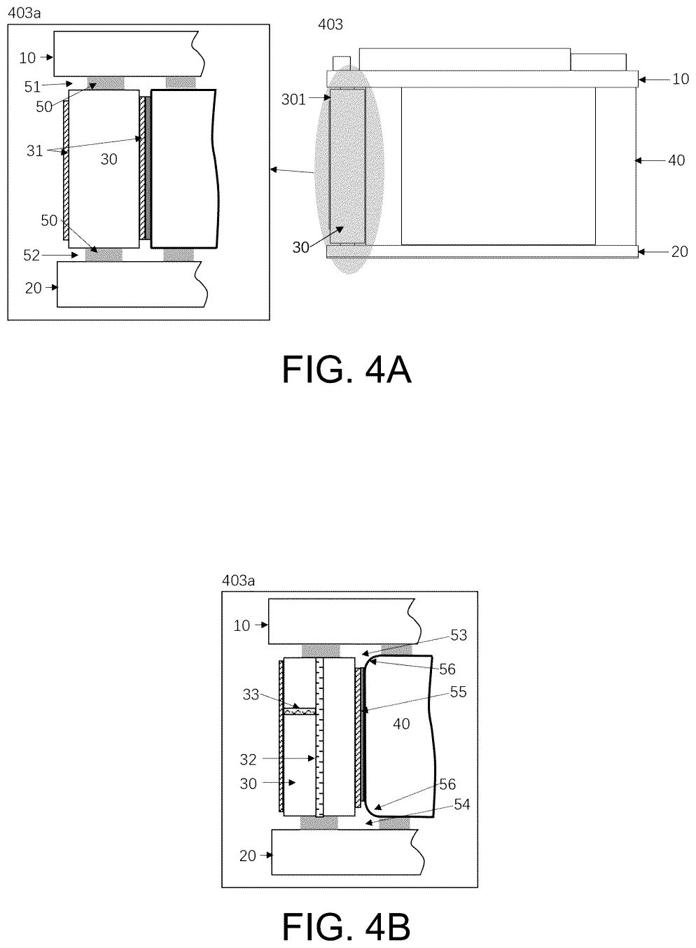

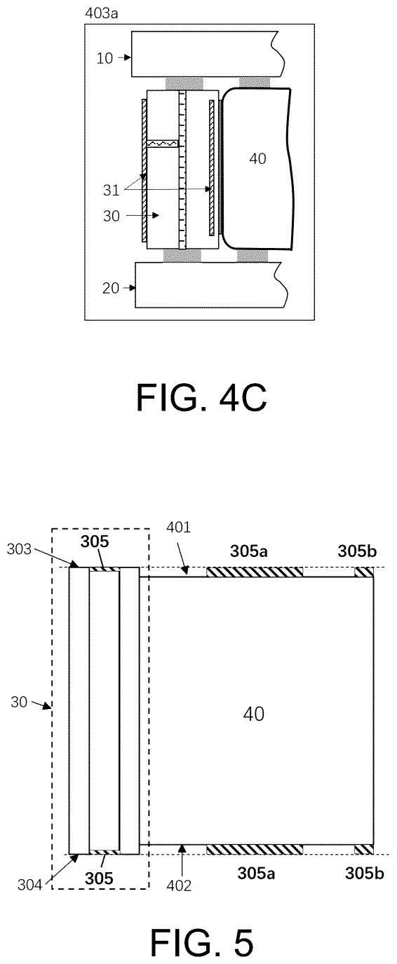

FIGS. 4A to 4C show a side view of the power supply module at the angle of the side surface 403, 403a is an enlarged layout diagram of the third substrate 30 and the surrounding device. As shown in FIG. 4A, a shielding layer 31 is provided on a first side surface 301 of a third substrate 30, a shielding layer 31 can also be provided on the second side surface 302, or a shielding layer 31 can be arranged on the first side surface 301 and the second side surface 302 simultaneously. The shielding layer can also be arranged inside the third substrate 30, as shown in FIG. 4C, a plurality of shielding layers can also be provided inside the third substrate 30, but provided on the surface of the third substrate 30 is optimal. The thickness of the shielding layer should be less than 1 OZ. By providing the shielding layer on the surface of the third substrate or inside the third substrate, the signal lead in the substrate is prevented from being interfered by the external signal.

On the other hand, as shown in FIG. 4B, the shielding layer 31 may be electrically connected to the metal frame 32 by means of the via hole 33; optionally, the shielding layer provided on the surface may be arranged in different zones, and the shielding layer of each zone is respectively connected to different potentials on the metal frame 32 to shield the interference of the electric field and the magnetic field.

The passive element 40 disclosed in the present invention may be an inductor or a transformer or the like, and the passive element 40 comprises at least two alternating current windings. As shown in FIG. 4B, the passive element 40 and the third substrate 30 are fixed by a bonding material 55. In order to prevent the conductive particles from flowing into the power supply module, the average thickness of the bonding material 55 is less than the spacing S1 between the metal layers on the upper surface 303 of the third substrate; optionally, the average thickness is less than (½)*S1, and even less than (⅓)*S1; and in the numerical value, the average thickness of the bonding material should be less than 100 μm, more preferably less than 50 μm, so as to the inflow of conductive particles can be more effectively prevented. On the other hand, a chamfer 56 is designed on two edges of the passive element adjacent to the third substrate, as shown in FIG. 4B; the radius of the chamfer 56 is less than 200 μm, and more preferably less than 100 μm. Due to the existence of the chamfer, a channel 53 exists among the passive element 40, the first substrate 10 and the third substrate 30, a channel 54 exists among the passive element 40, the second substrate 20 and the third substrate 30. The presence of the channel 53/54 increases the risk of the conductive particles flowing into the power supply module, and therefore, the channel 53/54 can be closed at both ends of the channel 53 and the two ends of the channel 54 by means of dispensing, thereby reducing the inlet of the conductive particles into the interior of the power supply module. In addition, by means of blocking glue at the gap 51 and the gap 52, the risk of the conductive particles flowing into the power supply module from the angle of the first side surface 301 is reduced; or by means of filling with the underfill material between the third substrate and the first substrate, and between the third substrate and the second substrate, the same effect can also be achieved.

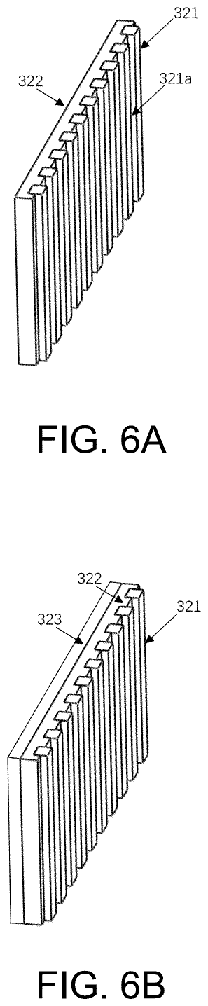

Furthermore, the height of the third substrate may not be lower than the height of the passive element, as shown in FIG. 5, the heights of the gaps 51 and 52 are further controlled. Furthermore, since the stack-type power supply module has a very high requirement for the welding flatness of the component, the height tolerance is generally required to be less than 100 μm. Therefore, in the present invention, the precision requirement of the combined process of the third substrate 30 and the passive element 40 is very high. In the present embodiment, the assembly difficulty is reduced by first combining the two together and then grinding. Due to the grinding process, the thickness of the exposed metal layer of the substrate is at least 0.2 mm. The specific steps are as follows:
Step 1: arranging the thickness of the exposed metal layer on the upper surface and the lower surface of the third substrate to be at least 0.2 mm, and bonding the third substrate and the passive element together by means of a bonding material to form a assembly;
Step 2: grinding the upper surface and the lower surface of the assembly;
Step 3: solder resist processing is performed on the upper surface and the lower surface of the assembly after grinding.

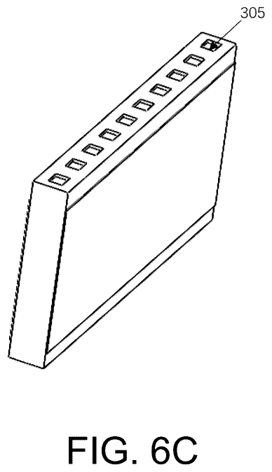

In addition, the present invention further discloses a method for manufacturing a third substrate and other structures, as shown in FIG. 6A to FIG. 6C. Referring to FIG. 6A, detailed steps are as follows with reference to FIG. 6A:
Step 1: first manufacturing a semi-etched copper frame 321;
Step 2: laminating a prepreg on one side of the semi-etching to form an insulating layer 322, as shown in FIG. 6A;
Step 3: continuing to etch on a side 321a where the copper frame is not semi-etched;
Step 4a: on the side of 321a, continuing to laminate the prepreg to form an insulating layer, the symmetrical structure of the third substrate is shown in FIG. 2A and FIG. 2B. The symmetrical structure can effectively prevent deformation of the third substrate, etc. and facilitate the provision of a shielding layer in the insulating layer or on the surface of the insulating layer.

In this embodiment, by performing double-sided etching on the copper frame, the wiring density can be further improved; on the other hand, more exposed surface of the surface of the copper frame is increased, and the soldering strength of the third substrate is further enhanced.

Optionally, the fourth step may also be Step 4b: stacking another insulating core plate 323 on the outer side of the insulating layer 322 by means of a low-temperature curing medium (such as a low-temperature curing prepreg, adhesive glue, etc.), so as to reduce warpage caused by asymmetry of the structure of the third substrate, as shown in FIG. 6B.

Optionally, in the step 2 and/or step 4a, the height of the insulating layer formed by lamination may be slightly higher than that of the metal layer 305, that is, the metal layer 305 is recessed within the upper surface 303 and the lower surface 304, and the gaps 51 and 52 between the third substrate 30 and the first substrate 10/the second substrate 20 may be further reduced.

In the present embodiment, only the copper frame is used as an example, and in other embodiments, other metal frames having good conductive characteristics may be used.

In another embodiment, an injection molding method may be used to first make a metal frame and then cover one surface of the metal frame using an injection molding process, or cover two opposite surfaces of the metal frame.

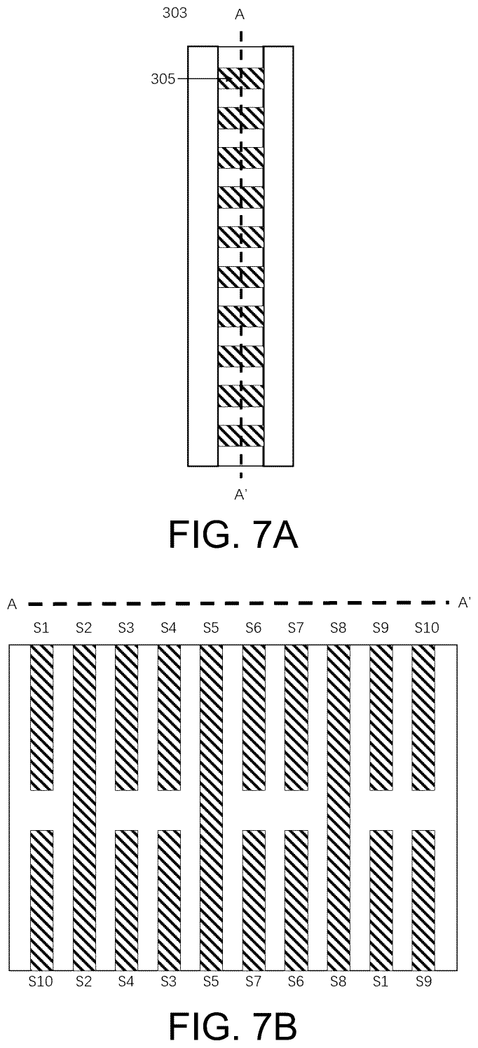

FIG. 7A and FIG. 7B show another structural layout of the metal frame, FIG. 7A is a top view of the upper surface 303 of the third substrate, and FIG. 7B is a side cross-sectional view taken along line A-A′ in FIG. 7A. Referring to FIG. 7B, the pin positions of the upper surface of the third substrate may be different from the pin positions of the lower surface, the third substrate is a multi-layer printed circuit plate or a composite multi-layer circuit plate, different pin positions of the upper surface and the lower surface are staggered in a staggered manner, and some signals are communicated through an internal wiring of the third substrate. The structure can optimize the arrangement of pin positions on the first substrate and the second substrate, reduce the wiring difficulty of the first substrate and the second substrate, and reduce the size of the power supply module. The signal pins shown in the present embodiment can also be prefabricated by using a metal frame, and at least part of the metal frames from the metal layer of the upper surface of the third substrate to the vertically corresponding metal layer of the lower surface of the third substrate is spilt in the middle, and are respectively electrically connected to other wiring layers by means of via holes, so as to realize the transfer of the signals between the first substrate and the second substrate.

The semiconductor device disclosed by the application can be used for realizing the functions of the switch disclosed by the application, such as a Si MOSFET, SiC MOSFET, GaN MOSFET or IGBT MOSFET.

The power supply module according to the above embodiments may also be a part of the electronic device, which may satisfy the technical features and benefits disclosed in the present disclosure.

The “equal” or “same” or “equal to” or “coplanar” disclosed by the application needs to consider the parameter distribution of engineering, and the error distribution is within +/−30%; and the included angle between the two line segments or the two straight lines is less than or equal to 45 degrees; the included angle between the two line segments or the two straight lines is within the range of [60, 120]; and the definition of the phase error phase also needs to consider the parameter distribution of the engineering, and the error distribution of the phase error degree is within +/−30%.

The embodiments in the specification are described in a progressive manner, each embodiment focuses on the difference from other embodiments, and the same similar parts between the embodiments can be referred to each other.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A power supply module for immersion cooling, comprising a first substrate, a third substrate, a passive element, a semiconductor device and a capacitor, wherein the first substrate comprises an upper surface and a lower surface opposite to each other, the semiconductor device is arranged on the upper surface of the first substrate, the capacitor is welded on the first substrate, and the lower surface of the first substrate is provided with a pad;
the third substrate comprises an upper surface and a lower surface opposite to each other, and a first side surface and a second side surface opposite to each other, the passive element comprises an upper surface and a lower surface opposite to each other, the upper surface of the third substrate and the upper surface of the passive element are attached to a lower surface of the first substrate, and a second side surface of the third substrate is disposed adjacent to one side surface of the passive element;
an upper surface and a lower surface of the third substrate are respectively provided with a metal layer, the first side surface is provided with an insulating layer, and the shortest distance between the first side surface and the edge of an adjacent metal layer is greater than zero;
a metal layer of the upper surface of the third substrate is fixed and electrically connected to a portion of the pads of the lower surface of the first substrate by means of a conductive material, a portion of the pads of the lower surface of the first substrate is disposed in a vertical projection of the third substrate on the lower surface of the first substrate, and the shortest distance between the vertical projection line of the first side surface of the third substrate on the lower surface of the first substrate and the adjacent portion of the pads on the lower surface of the first substrate is greater than zero;
the upper surface and the lower surface of the passive element are respectively provided with a metal layer, and the metal layer on the upper surface of the passive element is fixed and electrically connected to a portion of the pads on the lower surface of the first substrate by means of a conductive material.

2. The power supply module of claim 1, further comprising a second substrate, wherein the second substrate comprises an upper surface and a lower surface, the upper surface and the lower surface are both provided with pads, the pads of the upper surface are fixed and electrically connected to the metal layer on the lower surface of the third substrate and the metal layer on the lower surface of the passive element by means of a conductive material, and the pads on the lower surface of the second substrate are used for being fixed and electrically connected to the external assembly.

3. The power supply module of claim 1, wherein a spacing between adjacent metal layers of the upper surface of the third substrate is greater than a gap height between the first substrate and the third substrate.

4. The power supply module of claim 3, wherein a spacing between adjacent metal layers of the upper surface of the third substrate is greater than twice a gap height between the first substrate and the third substrate, and the gap height is less than 0.2 mm.

5. The power supply module of claim 2, wherein a spacing between adjacent metal layers of the lower surface of the third substrate is greater than a gap height between the second substrate and the third substrate.

6. The power supply module of claim 5, wherein a spacing between adjacent metal layers of the lower surface of the third substrate is greater than twice a gap height between the second substrate and the third substrate, and the gap height is less than 0.2 mm.

7. The power supply module of claim 1, wherein a width of the metal layer of the third substrate is greater than or equal to a shortest distance from an edge of the metal layer of the third substrate to the first side surface and/or the second side surface of the third substrate.

8. The power supply module of claim 7, wherein a width of the metal layer of the third substrate is greater than or equal to 0.2 mm, and a shortest distance from an edge of the metal layer of the third substrate to the first side surface and/or the second side surface of the third substrate is equal to 0.2 mm.

9. The power supply module of claim 1, wherein the third substrate and the passive element are fixed by a bonding material, and an average thickness of the bonding material is less than a spacing between adjacent metal layers of the upper surface of the third substrate.

10. The power supply module of claim 9, wherein an average thickness of the bonding material is less than ½ of a spacing between adjacent metal layers of the upper surface of the third substrate.

11. The power supply module of claim 1, wherein a vertical projection of the third substrate on the lower surface of the first substrate is within the lower surface of the first substrate, and a shortest distance between an edge of the vertical projection and an edge of the lower surface of the adjacent first substrate is greater than zero.

12. The power supply module of claim 1, wherein an edge of the passive element adjacent to the third substrate and the first substrate comprises a chamfer, a channel exists among the passive element, the first substrate and the third substrate, dispensing glue at both ends of the channel.

13. The power supply module of claim 2, wherein an edge of the passive element adjacent to the third substrate and the second substrate comprises a chamfer, a channel exists among the passive element, the second substrate and the third substrate, dispensing glue at both ends of the channel.

14. The power supply module of claim 1, wherein a gap between the first substrate and the third substrate is blocked with glue, or apply an underfill material to the gap.

15. The power supply module of claim 2, wherein a gap between the second substrate and the third substrate is blocked with glue, or apply an underfill material to the gap.

16. The power supply module of claim 1, wherein the third substrate comprises a metal frame, and the metal frame is electrically connected to the metal layer on the upper surface and on the lower surface of the third substrate.

17. The power supply module of claim 16, wherein the pin positions of the metal layer of the upper surface of the third substrate and the pin positions of the metal layer of the lower surface of the third substrate are in one-to-one correspondence, and the metal frame directly extends from the metal layer of the upper surface to the metal layer of the lower surface.

18. The power supply module of claim 16, wherein at least part of the pin positions of the metal layer of the upper surface of the third substrate and the pin positions of the metal layer of the lower surface of the third substrate are staggered, and at least part of the metal frame from the metal layer of the upper surface of the third substrate to the vertically corresponding metal layer of the lower surface of the third substrate is split in the middle.

19. The power supply module of claim 16, wherein the third substrate further comprises a shielding layer, and the shielding layer is disposed on a side surface of the third substrate and/or inside the third substrate.

20. The power supply module of claim 19, wherein the shielding layer is disposed between the metal frame and the passive element.

21. The power supply module of claim 19, wherein the third substrate is a multi-layer circuit plate, and the shielding layer is electrically connected to the metal frame through a via hole.

22. The power supply module of claim 21, wherein the shielding layer is configured in different zones, and the shielding layer of each zone is connected to different potentials on the metal frame.

23. The power supply module of claim 1, wherein the metal layer on the upper surface of the third substrate is recessed in the upper surface, and the metal layer on the lower surface of the third substrate is recessed in the lower surface.

24. The power supply module of claim 1, wherein a height of the third substrate is greater than a height of the passive element.

25. A method for manufacturing the third substrate of any one of claim 1, wherein the third substrate is formed by injection molding, first manufacturing a metal frame, then covering one surface or two opposite surfaces of the metal frame using an injection molding process.

26. The manufacturing method of the third substrate of claim 1, wherein the third substrate is manufactured by using a printed circuit plate embedded copper process, and comprises the following steps:
Step 1: first manufacturing a semi-etched copper frame;
Step 2: laminating a prepreg on one side of the semi-etching to form an insulating layer;
Step 3: continually etching on the side of the copper frame unetched.

27. The manufacturing method of claim 26, wherein the step of manufacturing the third substrate further comprises:
Step 4a: on the side of continuing etching in Step 3, continuing to laminate the prepreg to form an insulating layer.

28. The manufacturing method of claim 27, wherein the step of manufacturing the third substrate further comprises:
Step 4b: stacking another insulating core plate on the outer side of the insulating layer of Step 2 by means of a low-temperature curing medium.

29. A signal connection substrate, comprising an upper surface and a lower surface opposite to each other, and a first side surface and a second side surface opposite to each other, wherein the signal connection substrate is a multi-layer circuit plate, and at least three metal layers are provided on the upper surface and the lower surface of the signal connection substrate respectively;
the pin positions of the metal layer of the upper surface and the pin positions of the metal layer of the lower surface are arranged in a staggered manner;
the signal connection substrate further comprises a shielding layer arranged on the first side surface of the signal connection substrate and/or on the second side surface of the signal connection substrate and/or in the signal connection substrate;
an insulating layer is provided between the metal layer and the first side surface;
the signal connection substrate is used for a stacked power supply module.

30. The signal connection substrate of claim 29, wherein the signal connection substrate further comprises a metal frame, and the metal frame is electrically connected to the metal layer of the upper surface and the metal layer of the lower surface.

31. The signal connection substrate of claim 30, wherein the multilayer circuit plate is a multilayer printed circuit plate or a composite multi-layer circuit plate.

32. The signal connection substrate of claim 30, wherein at least part of the metal frame between the metal layer of the upper surface and the vertically corresponding metal layer of the lower surface is split in the middle, and the metal layer of the upper surface and the metal layer of the lower surface with the same pin position are electrically connected through the metal frame, the via hole and the inner wiring layer.

33. The signal connection substrate of claim 30, wherein the shielding layer is electrically connected to the metal frame through a via hole.

34. The signal connection substrate of claim 33, wherein the shielding layer is arranged in different zones, and a shielding layer of each zone is connected to different potentials on the metal frame.

35. The signal connection substrate of claim 30, wherein the metal layer on the upper surface of the third substrate is recessed in the upper surface, and the metal layer on the lower surface of the third substrate is recessed in the lower surface.

36. The signal connection substrate of claim 29, wherein a shortest distance from an edge of the metal layer to the first side surface and/or the second side surface of the signal connection substrate is greater than or equal to 0.2 mm.

37. A method for manufacturing a signal connection substrate of claim 30, wherein the signal connection substrate is manufactured by using a printed circuit plate embedded copper process, and comprises the following steps:
Step 1: first manufacturing a semi-etched copper frame;
Step 2: laminating a prepreg on one side of the semi-etching to form an insulating layer;
Step 3: continually etching on the side of the copper frame unetched.

38. The manufacturing method of claim 37, wherein the step of manufacturing the signal connection substrate further comprises Step 4a: on the side of continuing etching in Step 3, continuing to laminate the prepreg to form an insulating layer.

39. The manufacturing method of claim 37, wherein the manufacturing step of the signal connection substrate further comprises Step 4b: stacking another insulating core plate on the outer side of the insulating layer of Step 2 by means of a low-temperature curing medium.

40. A method for manufacturing a signal connection substrate of claim 30, wherein the signal connection substrate is formed by injection molding, first manufacturing a metal frame, then covering one surface or two opposite surfaces of the metal frame using an injection molding process.

41. A assembly, wherein the assembly is used for a stacked power supply module, comprising an upper surface and a lower surface opposite to each other, a signal connection substrate and a passive element; the signal connection substrate comprises an upper surface and a lower surface opposite to each other, and a first side surface and a second side surface opposite to each other; the passive element comprises an upper surface and a lower surface opposite to each other; the second side surface of the signal connection substrate is arranged adjacent to one side surface of the passive element; the upper surface and the lower surface of the signal connection substrate are respectively provided with a metal layer, and the metal layer on the upper surface of the signal connection substrate is electrically connected to the corresponding metal layer of the lower surface;
an insulating layer is disposed between the metal layer and the first side surface of the signal connection substrate;
the upper surface and the lower surface of the passive element are respectively provided with a metal layer, and the upper surface and the lower surface of the passive element each comprises at least one metal layer for transmitting power;
the metal layer of the upper surface of the signal connection substrate is coplanar with the metal layer of the upper surface of the passive element, and the metal layer of the lower surface of the signal connection substrate is coplanar with the metal layer of the lower surface of the passive element;
a shortest distance between the first side surface and an edge of an adjacent metal layer is greater than zero.

42. The assembly of claim 41, wherein the passive element is a magnetic element comprising at least two alternating current windings.

43. The assembly of claim 41, wherein the passive element further comprises at least one direct current pin, and the direct current pin covers a part of the upper surface, a part of a side surface and a part of the lower surface of the passive element, and is used for transferring energy between the upper surface and the lower surface of the passive element.

44. The assembly of claim 41, wherein the second side surface of the signal connection substrate is provided with an insulating layer.

45. The assembly of claim 44, wherein the thickness of the insulating layer is at least 0.2 mm.

46. The assembly of claim 41, wherein the passive element and the signal connection substrate are fixed by a bonding material.

47. A method for manufacturing the assembly of claim 41, comprising the following steps:
Step 1: setting the thickness of the exposed metal layer on the upper surface and the lower surface of the signal connection substrate to be at least 0.2 mm, and bonding the signal connection substrate and the passive element together by means of a bonding material to form an assembly;
Step 2: grinding the upper surface and the lower surface of the assembly;
Step 3: solder resist processing is performed on the upper surface and the lower surface of the grinded assembly.
